(19) United States
(12) Patent Application Publication
(10) Pub. No.: US 2014/0224303 A1
(43) Pub. Date: Aug. 14, 2014

(54) PHOTOVOLTAIC SYSTEM FOR INSTALLATION ON ROOFS, WITH PLASTIC SUPPORT AND PHOTOVOLTAIC MODULE

(71) Applicants: Peter Herwig, Aschaffenburg (DE); Nicolas Muller, Courcelle-Chaussy (FR); Stefan Fleckenstein, Weibersbrunn (DE); Andre Schäfer, Speyer (DE); Michael Prinz, Forst (DE); Andreas Mägerlein, Mannheim (DE); Matthias Dietrich, Weinheim (DE)

(72) Inventors: Peter Herwig, Aschaffenburg (DE); Nicolas Muller, Courcelle-Chaussy (FR); Stefan Fleckenstein, Weibersbrunn (DE); Andre Schäfer, Speyer (DE); Michael Prinz, Forst (DE); Andreas Mägerlein, Mannheim (DE); Matthias Dietrich, Weinheim (DE)

(73) Assignee: BASF SE, Ludwigshafen (DE)

(21) Appl. No.: 14/123,642

(22) PCT Filed: May 3, 2012
(86) PCT No.: PCT/EP2012/001896

§ 371 Date: Mar. 5, 2014

(30) Foreign Application Priority Data
Jun. 3, 2011 (DE) 10 2011 104 303.2

(51) Int. Cl. H01L 31/042; H01L 21/64; H01L 31/048

(52) U.S. Cl. CPC H01L 31/0422; H01L 31/0483; H01L 21/64
USPC 136/251; 248/220.21; 248/49; 264/328.1

(57) ABSTRACT

The invention relates to a photovoltaic system with a plastic support and a photovoltaic module for installation on roofs. The plastic support (1) may be mounted directly to a roof substructure, so that an additional roof covering can be dispensed with. The photovoltaic modules may be fixed on the plastic support (1) without screwing.

The invention generally relates to photovoltaic systems. In particular, the invention relates to a system for on roof installation of photovoltaic systems.

A variety of supports for mounting photovoltaic modules on roofs of houses are known from prior art.

Often in the previous fastening systems, the photovoltaic modules are fixed to the support using screw clamps. Screw fastening is comparatively time-consuming. Also, common supports usually require a large number of individual parts for assembly, inter alia the screw clamps mentioned above.

Accordingly, the assembly is complex. This results in the fact that installation costs make up a non-negligible percentage of the investment costs of a photovoltaic system. So currently even in large-scale projects a proportion of more than 15% out of the total amount invested has to be calculated for installation costs. Of additional importance is that this percentage will be rising with falling module prices.

Another drawback of existing roof-mounted photovoltaic systems is the additional weight resulting from the support. So under certain circumstances the total weight of the system may exceed the total allowable load of the roof structure. In this case, the roof structure would have to be reinforced.

Therefore, an object of the invention is to provide a photovoltaic system that is fast and easy to install, whilst also being lightweight. This object is solved by the subject matter of the independent claims. Advantageous embodiments and refinements of the invention are set forth in the respective dependent claims.

According to the invention, a roof-integrated photovoltaic system with plastic supports is proposed.

The roof-integrated photovoltaic system with plastic supports is an optimized solution especially for large photovoltaic systems. Furthermore, the invention is also particularly suitable for accompanying roof restoration, for example of fiber cement roofs, if during the roof renovation the roof covering is replaced.

The photovoltaic system according to the invention essentially comprises two parts. One part is a plastic support, the other part is the photovoltaic module. The plastic support may be attached directly to a roof substructure, so that additional roof covering may be omitted. In this way, the load on the roof substructure imposed by the whole roof construction is considerably reduced. An extra contribution is attributable to the plastic support which by virtue of its material, generally, is lighter than for example a metal support of comparable dimensions.

Furthermore, the invention distinguishes by the fact that the photovoltaic modules may be mounted on the plastic support without using screws, in particular by means of a snap or bayonet connection. That means, once the plastic supports are mounted on the roof, the photovoltaic modules may be mounted without tools, by means of a latching mechanism on each of the plastic supports.

The invention will now be explained in more detail by exemplary embodiments and with reference to the accompanying drawings. Identical reference numerals in the drawings designate identical or corresponding elements. In the drawings:

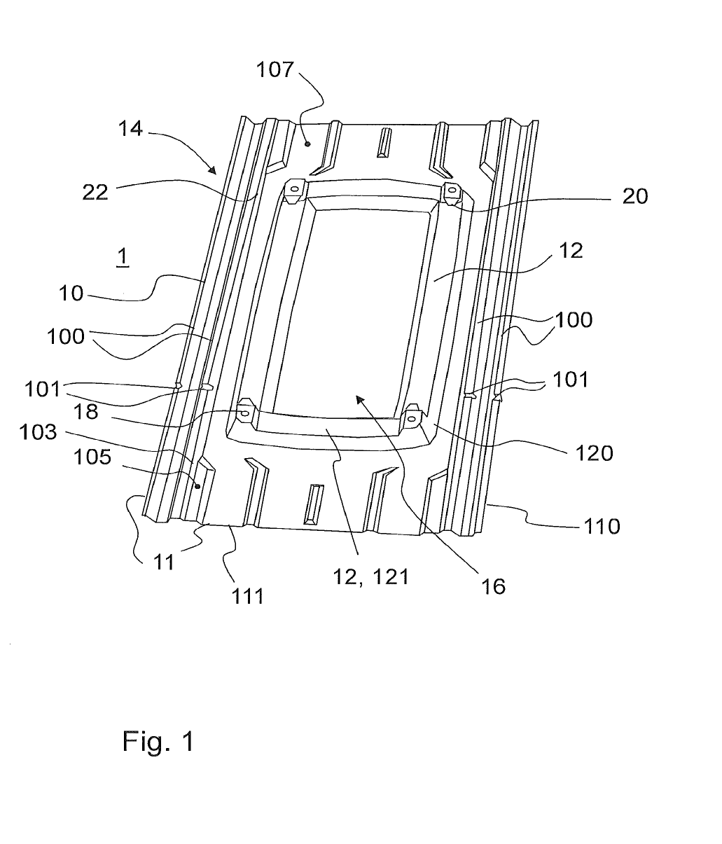

FIG. 1 is a view of the plastic support;

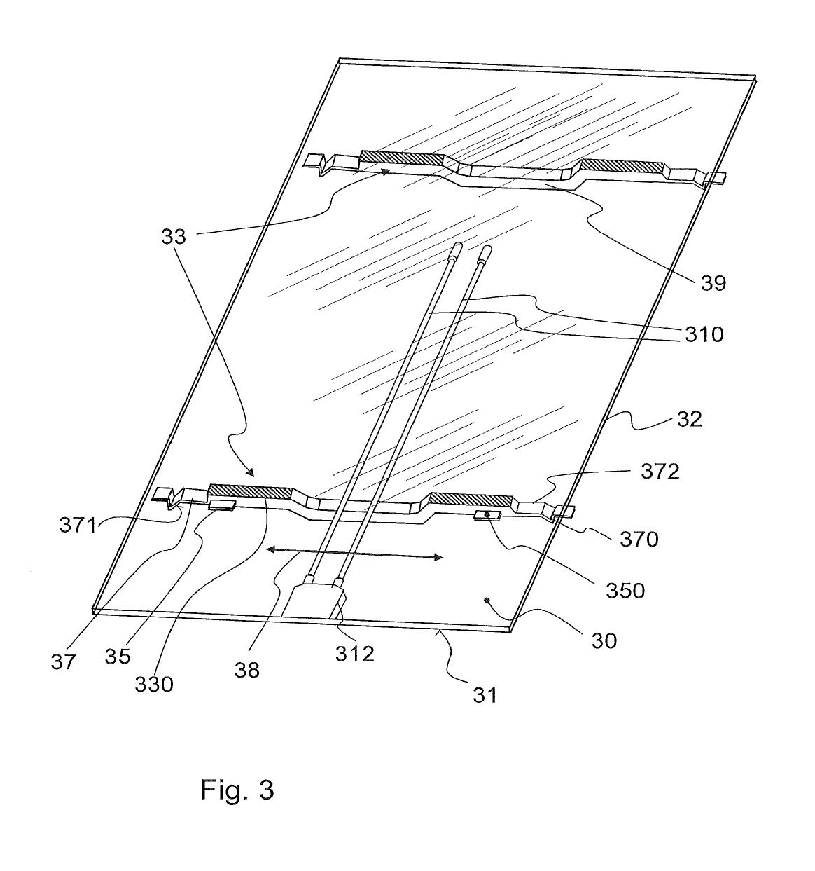

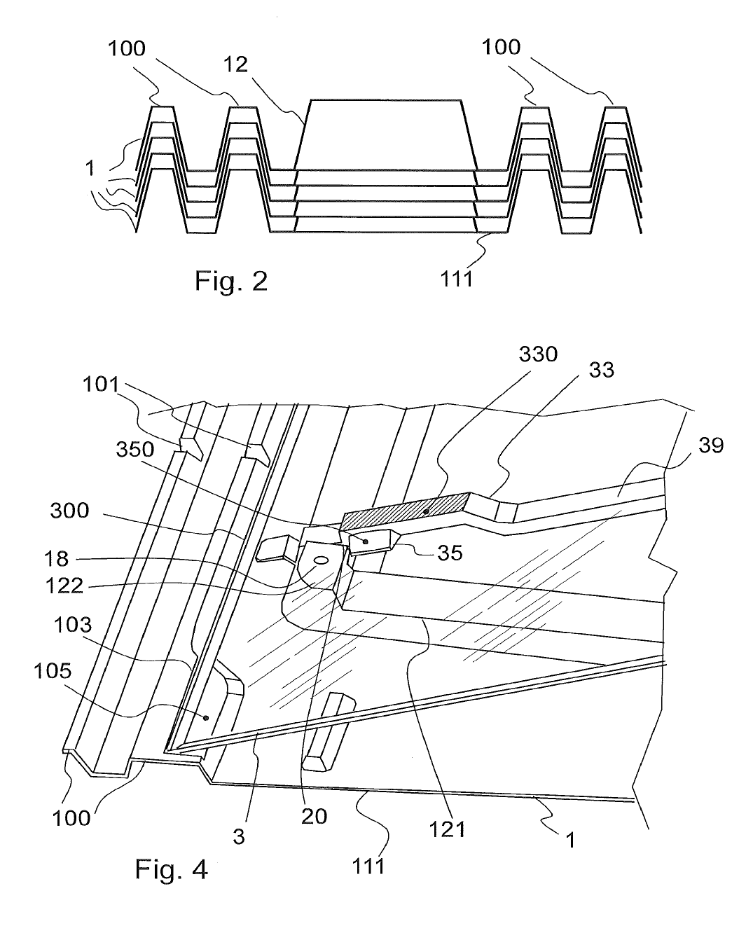

FIG. 2 shows a plurality of stacked plastic supports;

FIG. 3 is a view of a photovoltaic module,

FIG. 4 illustrates in an enlarged view, based on the elements shown in FIGS. 1 and 3, a first method step for fixing a photovoltaic module on the plastic support 1;

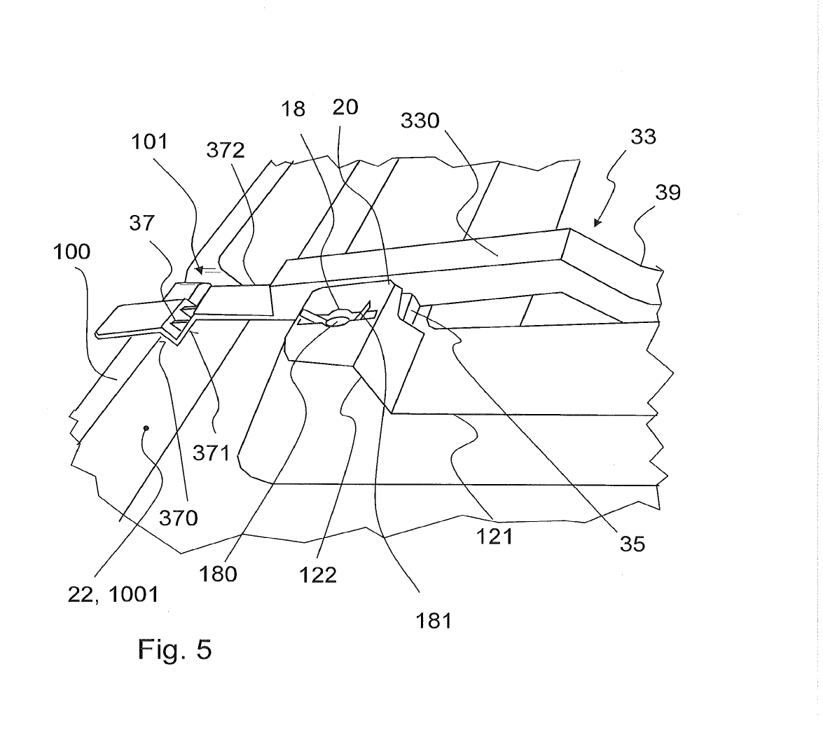

FIG. 5 shows a section of a photovoltaic installation system with the photovoltaic module being latched on the plastic support.

FIG. 1 shows a view of the upper side 14 of a plastic support 1, also referred to as a tray below, for a photovoltaic module to be fixed thereon. The upper side 14 in the context of the invention is that side of plastic support 1 on which the photovoltaic module is attached and which upon installation into a roof surface faces upwards. The plastic support 1 according to the invention, as exemplarily shown in FIG. 1, is formed as a one-piece molded plastic element, having a rectangular or square outline. Plastic support 1 is in form of a flat or planar component in which structures project from a flat, plate-like area that forms a base plane 107. Along a first lateral direction, plastic support 1 has rainwater discharging elements 10 which, when plastic support 1 is in an inclined position, guide rain water along this lateral direction or in the direction of the gradient. In particular it is useful to provide elongated rainwater discharging elements 10 extending along an edge 110 of plastic support 1 and projecting from base plane 107. Accordingly, the rain water is then guided in the direction along this edge. Plastic supports 1 then are suitably mounted on a roof in such a manner that along this edge 110 there is a steeper gradient as compared to the neighboring edges which are referred to as transverse edges 111 below. Preferably, the direction of the gradient is along edge 110. Plastic support 1 furthermore has a shape in form of an raised portion 12 on its upper side 14, with an edge 120 that is spaced from the border 11 of plastic support 1. Mounting points 18 are provided on raised portion 12 for passing fastening means through plastic support 1 and fastening them to a substructure. In addition, plastic support 1 has detent members 20, 22 for snap fixing a photovoltaic module. These detent members allow to fix the photovoltaic module, in particular in conjunction with detent members of a matching photovoltaic module, without any further tool requiring measures such as screw connections.

Mounting points 18 may especially heir form of through holes for establishing screw connections. The raised portion 12 in the center of the plastic support and the arrangement of the mounting points thereon ensure that rain water is directed along edge 120 of the raised portion and hence circumvents mounting points 18. Thus, rainwater sealing for the mounting points 18 is achieved in a very simple way.

As can furthermore be seen from FIG. 1, mounting points 18 are arranged offset inwardly from border 11. Preferably, a mounting point 18 is spaced from border 11 by at least one sixth, preferably by at least one fifth of the width of plastic support 1. In contrast to a peripheral assembly, a result thereof is that the mounting points 18 are distributed as evenly as possible when arranging the plastic supports on the roof in side by side relationship, which provides for a better distribution of forces in case the mounted modules are subjected to suction and/or pressure moments.

In order to better dissipate suction and pressure forces, it is especially intended, as in the embodiment shown in FIG. 1, to arrange the detent members 20 which accommodate vertical forces close to the mounting points 18. In the embodiment shown in FIG. 1, detent members 20 are arranged directly adjacent to the mounting points. Thereby, the flux of forces in the system is adapted such that an occurring pressure/suction load is transmitted directly into the roof construction—which is the optimum way. By contrast, in currently common on-roof systems the module attachment point is typically located at the outer module frame and therefore far away from the point of force transmission into the substructure. Therefore, in order to provide for an optimum transmission of suction and pressure loads to the roof substructure, without any limitation to the special embodiment of the invention shown in FIG. 1, detent members 20 are provided for locking in the direction perpendicular to the upper side of a photovoltaic module 3 or perpendicular to the upper side of plastic support 1, which are spaced from the closest mounting point 18 by not more than one sixth, preferably not more than one tenth of the longest lateral dimension of plastic support 1.

Particularly preferable, as shown in FIG. 1, is a raised portion 12 in form of a raised bead 121 which frames an opening 16 in plastic support 1. Opening 16 provides for good ventilation of the photovoltaic modules. Moreover, the weight of plastic support 1 is reduced and material is saved.

In other words, the preferably four mounting points 18, in particular screwing points, of plastic support 1 are thus arranged at a raised bead which lies out of the water guidance. In particular mounting points 18 may be arranged such that they are covered by the subsequently placed photovoltaic module and so are protected to an optimum from rain and splash water.

Basically, rainwater discharging elements 10 are formed such that rainwater which runs off obliquely is guided in the direction of the gradient, i.e. in the direction along one edge of the plastic support and thus cannot run off laterally. Accordingly, the plastic supports 1 according to the invention permit to achieve a rainproof roof sealing.

In order to obtain a rainwater-tight seal when placing the plastic supports 1 side by side, in a modification of the invention beads 100 are provided as rainwater discharging elements 10 on both sides of the raised portion along the edges of plastic support 1, which beads have complementary shaped upper and lower sides, so that two plastic supports 1 may be placed in laterally offset relationship one on top of the other with complementary interengaging beads 100. The beads 100 not only prevent water that runs off in an angle to the direction of the gradient from running off via the lateral edge of plastic supports 1 and thus penetrating into the roof. Such beads 100, if provided at both sides, also allow for a selective installation direction when mounted on the roof. That means, plastic supports 1 may be placed in overlapping relationship in the horizontal direction, both from right to left or in the opposite direction, which reduces the installation effort involved.

So according to the invention, water is directly guided on the plastic support, without requiring additional measures (such as additional gutters or seals). Rainproofing in both the horizontal direction and the vertical, direction is ensured by corresponding overlappings according to the rules for the roofing trade.

In order to ensure water tightness in the vertical direction, i.e. in the direction of the roof gradient, and to permit a simple placement of the plastic supports along this direction in overlapping relationship, the plastic support 1 according to yet another embodiment of the invention additionally has complementary molded shapes at the upper and lower sides along transverse edges 111. As can be seen from FIG. 1, in the illustrated embodiment this modification is also implemented by beads 100, and by optional further molded elements.

The complementary molded shapes at the front and back sides of plastic support 1 provide for an easy and precise side by side placement of plastic supports 1 on the roof. The first module tray, or first plastic support 1, may be positioned on the roof by appropriate measuring. All further plastic supports 1 are automatically positioned by the lateral and vertical overlap, so that the measuring effort is limited to a minimum. By contrast, the measurement effort for currently common on-roof or in-roof systems is much more complex.

Plastic supports 1 may generally be formed as identical parts, i.e. each plastic support 1 may thus be mounted at any point of a module array. This allows for an easy installation of plastic supports 1 and also optimizes logistics in terms of packaging (each support 1 can be packed in the same manner) and transportation. In view of the latter, according to one embodiment of the invention, plastic support 1 is stackable and therefore designed to save space during transport. A stackable plastic support 1 in the context of the invention is to be understood as a plastic support having molded shapes with at least partially complementary upper and lower surfaces, so that when placing one plastic support 1 with its bottom side on top of another plastic support 1 with the edges aligned, the total height of the thus stacked two plastic supports will be less than twice the height of a single plastic support 1.

FIG. 2 shows an example thereof. FIG. 2 schematically illustrates five stacked plastic supports 1, viewed in the direction towards transverse edge 111. As can be seen from FIG. 2, both the beads 100 on both sides and the raised portion 12 are molded complementary at the top and bottom surface thereof, so that plastic supports 1 may be stacked one on top of the other.

Basically, any thermoplastically processable polymer may be used as the plastic material in the method according to the invention. Therefore, according to a preferred embodiment of the invention the plastic support is manufactured from a thermoplastic molding compound. Particularly suitable are one or more plastics selected from polyethylene, polypropylene, polyvinyl, chloride, polystyrene, high impact polystyrene (HIPS), acrylonitrile-butadiene-styrene copolymers (ABS), acrylonitrile-styrene-acrylate copolymers (ASA), methacrylate-acrylonitrile-butadiene-styrene copolymers (MABS), styrene-butadiene block copolymers, polyamide, polyethylene terephthalate (PET), polyethylene terephthalate glycol (PETG), polybutylene terephthalate (PBT), polyoxymethylene (POM), polycarbonate (PC), polymethyl methacrylate (PMMA), poly(ether)sulfones, thermoplastically processable polyurethane (TPU), and polyphenylene oxide (PPO).

Particularly preferred polymers are polyamides.

The mentioned plastics may be used in pure form or mixed with conventional plastic additives. In a preferred embodiment, plastics with added fibrous or particulate fillers are used.

It has been found that the thermoplastic molding compound is still mold-processable with a proportion of fibrous and/or particulate fillers of up to 70 percent by weight, preferably in a range from 10 to 60 percent by weight, more preferably in a range from 20 to 50 percent by weight, in particular by injection molding or injection compression molding, to produce the relatively large-area plastic supports 1 according to the invention. The high proportion of fiber and/or particulate fillers thereby enhances the strength and durability of plastic support 1.

According to vet another embodiment, pigments and/or stabilizers are added to the thermoplastic molding compound to improve the weather resistance and fire properties. These pigments and/or stabilizers may be a portion of the fibrous or particulate fillers mentioned above, or may be added in addition to the fibrous or particulate fillers.

Particularly suitable fillers are glass fibers, glass beads, mineral fillers, or so-called nanoparticles.

Especially preferred plastics are glass fiber reinforced polyamides. In principle, all known polyamides are suitable as the polyamide. Examples of such polyamides considered are polyamides with an aliphatic, semi-crystalline, or partly aromatic structure or amorphous structure of any kind, and blends thereof, including polyether amides such as polyether block amides.

Semi-crystalline or amorphous resins having a molecular weight (weight average) of at least 5000, such as described e.g. in U.S. Pat. Nos. 2,071,250; 2,071,251; 2,130,523; 2,130,948; 2,241,322; 2,312,966; 2,512,606; and 3,393,210 are preferred.

Examples thereof are polyamides derived from lactams having from 7 to 13 ring members, such as polycaprolactam, polycapryllactam, and polylaurolactam, and polyamides obtained by reacting dicarboxylic acids with diamines.

Dicarboxylic acids that can be used are alkane dicarboxylic acids having from 6 to 12, in particular from 6 to 10 carbon atoms, and aromatic dicarboxylic acids. Such acids include, among others, adipic acid, azelaic acid, sebacic acid, dodecanedioic acid (=decane dicarboxylic acid), and terephthalic acid and/or isophthalic acid.

Suitable diamines are in particular alkanediamines with 6 to 12, especially 6 to 8 carbon atoms, and m-xylylenediamine, di(4-aminophenyl)methane, di(4-aminocyclohexyl)methane, di(4-amino-3-methylcyclohexyl)methane, isophorone diamine, 1,5-diamino-2-methyl-pentane, 2,2-di(4-aminophenyl)propane, or 2,2-di(4-aminocyclohexyl)propane.

Preferred polyamides are in particular polyhexamethylene adipamide (PA 66) and polyhexamethylene sebacimide (PA 610), polycaprolactam (PA 6), and copolyamides 6/66, in particular with a proportion from 5 to 95 wt % of caprolactam units.

Preferred is a polyamide selected from PA 6, PA 66, and copolyamide 6/66; most preferred is PA 6,

Other suitable polyamides are obtainable from omega-aminoalkyl nitriles such as aminocapronitrile (PP 6) and adipodinitrile with hexamethylenediamine (PA 66) through so-called direct polymerization in the presence of water, such as for example described in patent applications DE 10313681, EP 1198491, and EP 922065.

In addition, polyamides are to be mentioned, which for example are obtainable by condensation of 1,4-diaminobutane with adipic acid at elevated temperature (polyamide 46).

Preparation processes for polyamides of this structure are described, e.g., in European patent applications EP 38094, EP 38582, and EP 39524.

Other examples are polyamides which are obtainable by copolymerization of two or more of the aforementioned monomers, or mixtures of several polyamides, wherein the mixing ratio is arbitrary.

Furthermore, partially aromatic copolyamides such as PA 6/6T and PA 66/6T with a triamine content of less than 0.5, preferably less than 0.3 wt %, have proved to be particularly advantageous (see EP 299444). Preparation of the partially aromatic copolyamides with low triamine content may be accomplished according to the methods described in European patent applications EP 129195 and EP 129196.

The following non-exhaustive list, includes the aforementioned and other polyamides in the sense of the invention and the contained monomers:

A-B polymers:

PA 6 ε-caprolactam

PA 7 ethanolactam

PA 8 caprylic lactam

PA 9 9-aminopel argonic acid

PA 11 11-aminoundecanoic acid

PA 12 laurolactam.

AABB-type polymers:

PA 46 tetramethylenediamine, adipic acid

PA 66 hexamethylenediamine, adipic acid

PA 69 hexamethylenediamine, azelaic acid

PA 610 hexamethylenediamine, sebacic acid

PA 612 hexamethylenediamine, decanedicarboxylic acid

PA 613 hexamethylenediamine, undecanedicarboxylic acid

PA 1212 1,12-dodecanediamine, decanedicarboxylic acid

PA 1313 1,13-diaminotridecane, undecanedicarboxylic acid.

PA 6T hexamethylenediamine, terephthalic acid

PA MXD6 m-xylylenediamine, adipic acid

PA 61 hexamethylenediamine, isophthalic acid

PA 6-3-T trimethylhexamethylenediamine, terephthalic acid.

PA 6/6T (see PA 6 and PA 6T)

PA 6/66 (see PA 6 and PA 66)

PA 6/12 (see PA 6 and PA 12)

PA 66/6/610 (see PA 66, PA 6, and PA 610)

PA 61/6T (see PA 61 and PA 6T)

PA 12 PACSV1 diaminodicyclohexylmethane, lauric lactam

PA 61/6T/PACM as PA 61/6T+diaminodicyclohexylmethane

PA 12/MACMI laurolactam, dimethyl-diamino-dicyclohexylmethane, isophthalic acid

PA 12/MACMT laurolactam, dimethyl-diamino-dicyclohexylmethane, terephthalic acid.

PA PDA-T phenylenediamine, terephthalic acid.

The polyamides and their preparation are known, for example from Ullmanns Encyklopädie der Technischen Chemie, 4^{th} ed., vol. 19, pp. 39-54, Verlag Chemie, Weinheim, 1980; Ullmanns Encyclopedia of Industrial Chemistry, Vol. A21, pp. 179-206, VCH Verlag, Weinheim 1992; Stoeckhert, Kunststofflexikon, 8^{th} ed., pp. 425-428, Carl Hanser Verlag Munich 1992 (keyword “Polyamide” and following), and Saechtling, Kunststoff-Taschenbuch, 27^{th} ed. Carl Hanser Verlag, Munich 1998, pp. 465-478.

The manufacturing of the preferred polyamides PA 6, PA 66 and copolyamide 6/66 will be briefly discussed below. The polymerization or polycondenzation of the starting monomers to the polyamide is preferably accomplished according to the conventional processes. For example, the polymerization of caprolactam may be accomplished according to the continuous processes described in German patent applications DE 1495198 and DE 2558480.

The polymerization of AH salt for the preparation of PA 66 may be accomplished according to the conventional batch process (see: Polymerization Processes pp. 424-467, especially pp. 444-446, Interscience, New York, 1977), or by a continuous process, e.g. according to European patent application EP 129196.

During polymerization, conventional chain transfer agents may be used concomitantly. Suitable chain transfer agents are e.g. triacetonediamine compounds (see WO 95/28443), monocarboxylic acids such as acetic acid, propionic acid, and benzoic acid, dicarboxylic acids such as adipic acid, sebacic acid, cyclohexane-1,4-dicarboxylic acid, isophthalic acid, and terephthalic acid, and basic amines such as hexametylenediamine, benzylamine, and 1,4-cyclohexyldiamine. The obtained polymer melt is discharged from the reactor, cooled and granulated.

The resulting granules may be subjected to a post-polymerization which usually takes from 2 to 24 hours. This is accomplished in conventional manner by heating the granules to a temperature T below the melting point Ts or crystalline melting point Tₖ of the polyamide. By such post-polymerization, the final molecular weight of the polyamide is set (measured as viscosity number VN, see details of VN further below). Suitable polyamides generally have a viscosity number VN from 50 to 250, preferably from 70 to 200, and more preferably from 80 to 150 ml/g, as determined according to ISO 307 EN on a 0.5 wt % solution of the polyamide in 96 wt % sulfuric acid at 25° C. These viscosity numbers correspond to high molecular weights.

Polyamides that are particularly suitable for the present invention are glass fiber reinforced, highly flowable and heat-resistant polyamides, such as those described in WO 2006/042705. Particularly suitable is Ultramid® “Highspeed” by BASF SE.

Several manufacturing techniques are considered as production methods for manufacturing the plastic supports according to the invention, such as e.g. thermoforming or injection molding. In case of thermoforming, first, plates are produced from the selected polymers in an extrusion process. These plates are then heated in the so-called thermoforming process, e.g. using IR lamps, and shaped in a three-dimensional thermoforming tool.

For manufacturing complex three-dimensional components from thermoplastic materials, such as the plastic supports according to the invention, injection molding has proven to be particularly suitable. Due to the component size, tools with hot runner systems are preferably used in this case.

By using a hot runner manifold which distributes the plastic melt to various nozzles, the flow path required for filling the mold can be significantly reduced.

For large-area components it is also possible to employ an injection molding process with cascade control. In this case, the plastic material is injected through several nozzles that are successively arranged in the flow direction of the plastic material. The injection of the plastic material is controlled such that the plastic material is injected through a nozzle only at the time when the nozzle is covered by the plastic material that was injected by the upstream nozzle with respect to the direction of flow of the injected plastic material. That means, the injection of the plastic material is staggered. Since in this manner the flow path to be traveled by the plastic material is limited, larger components may be produced in spite of the small wall thickness.

Another special process which has proved to work well, especially for large components, is injection compressing molding.

Here the tool is not completely closed at the beginning. Therefore, the tool gap through which the plastic melt, has to flow has a greater height which results in a lower pressure loss. In this method, the tool is not completely closed until the melt has been injected partially or completely into the mold tool. The embossing step may be effected on the one hand by the movement of one tool half, or on the other by using movable mold tool inserts, which are controlled hydraulically, for example.

According to another special process which in particular enables to reduce the required injection pressure on the one hand and the warpage on the other, especially for large components, physical or chemical blowing agents are used for the injection molding or injection compression molding process.

According to one embodiment of the invention, automatic tolerance compensation may be achieved with the plastic supports of the invention. Each roof exhibits a more or less pronounced unevenness. In case of on-roof modules this has usually been compensated for by adjusting the roof hooks, in case of common in-roof systems by leveling the substructure.

However, a plastic support element according to the invention may in particular be formed to be twistable. Suitable for this purpose are the plastic materials mentioned above, in particular fiber-reinforced polyamides. Polyamides distinguishes from other thermoplastics by high elasticity, which enhances twistability. Furthermore, preferably, as in the embodiment shown in FIG. 1, molded shapes with parallel or substantially parallel longitudinal extensions are provided along the edge, or in the proximity of the border 11. In the illustrated embodiment, these molded shapes are in particular provided by parallel extending beads 100. In this manner, twisting about an axis along the longitudinal extension of beads 100, or more generally of rainwater discharging elements 10, is facilitated. This allows to compensate for height differences of a substructure below the plastic support 1 of up to 10 mm. This amount refers to a plastic support 1 intended for a module size of 1685 mm×993 mm.

A major risk factor in roof-integrated photovoltaic systems is cabling and the associated risk of pinching the cable. When setting down the module or directly during installation the cable may get pinched or crushed between the substructure and the module. To prevent this, in one embodiment of the invention a recess for cable routing is integrated in plastic support 1. Thus, the photovoltaic modules 3 may be safely connected to one another. As shown in FIG. 1, the recess is provided as a cable channel 101 which is open at the top, formed into beads 100. However, cable channel 101 only interrupts an upper portion of beads 100, so that it is avoided that runoff rainwater runs off transversely through cable channel 101 and comes under the overlapping plastic supports 1 that are attached side by side and penetrates into the roof. In other words, cable channel 101 extends above the base plane 107 of the plastic support on which the water runs off. Accordingly, in one embodiment of the invention, at least one cable guide element is provided in plastic support 1, preferably in form of a half-open cable channel which extends above a base plane 107 of plastic support 1.

A photovoltaic module according to one embodiment of the invention and intended to be matched with plastic support 1 will now be described.

Generally, plastic support 1 allows the use of a frameless module, especially one that is configured as a double glass module.

FIG. 3 illustrates a photovoltaic module 3 according to one embodiment of the invention. FIG. 3 shows a view of the front side 30 of photovoltaic module 3, i.e. the photovoltaically active side. Photovoltaic module 3 comprises a glass sheet 32 as a substrate or cover of the photoactive layer of module 3. For illustration purposes, glass sheet 32 is represented transparently to make visible the rear-mounted fastening elements.

FIG. 3 illustrates connection cables 310 which are connected to a junction box 312. During assembly of the photovoltaic module 3 on the plastic support, these connection cables 310 are inserted into cable channels 101. Thereby it is avoided that during the subsequent lateral displacement of photovoltaic module 3 for locking it on plastic support 1, cables 310 get pinched and damaged between the module and plastic support 1.

The photovoltaic module according to the invention comprises module holders 33 attached, preferably glued, to the back side 31 thereof, which at the same time serve for fixing to the plastic support 1. Due to this way of attachment and the configuration of the module holder with detent members, the need for a module frame is eliminated, the typical tasks of a module frame (attachment points and stiffening of the module) are performed by module holders 33 and through the fixation to plastic support 1 described below.

Each module holder 33 is glued to the back side 31 with at least one gluing surface 330. Preferably, back side 31 as well as front side 30 each are formed by a glass sheet, the photoactive layer being disposed between the glass sheets. Accordingly, photovoltaic module 3 is a frameless double glass module.

Current conventional modules have to be handled on the somewhat unwieldy module frame. In one embodiment of the invention, by contrast, handles 39 are formed on module holders 33, which allow for easy and safe handling of photovoltaic module 3.

Photovoltaic module 3 has detent members 35, 37 in correspondence to the detent members 20, 22 of plastic support 1. In the example shown in FIG. 3, the latching direction 38 is along the longitudinal extension of module holders 33. In order to lock photovoltaic module 3 in a direction perpendicular to the surface, detent members 35 are provided in form of detent lugs which protrude from the base body of module holder 33 transversely to latching direction 38. For locking in vertical, direction, detent lugs 35 have detent surfaces 350 which preferably are in parallel to the front 30 or back 31 sides of the photovoltaic module and in any case define engaging points for a corresponding detent member of plastic support 1 which block a vertical, displacement in the direction perpendicular to front side 30. In other words, detent surfaces 350 have a component of the surface normal in parallel to the direction of the surface normal of front side 30 or back side 31 to block a movement in the direction of this surface normal when engaged by a detent member of a support.

Further detent members 37 are provided in form of resiliently mounted hooks. Hooks 37 have a locking surface 370 extending transversely with respect to the latching direction 38, and a guiding surface 371 extending at an angle to latching direction 38 and thus also at an angle to back side 31. Latching hooks 37 are resiliently mounted such that they may be deflected in a direction transversely to back side 31.

On each module holder 33 a pair of hooks 37 are provided, the hooks being aligned in opposite directions, i.e. mirror-inverted to each other. This arrangement of the detent members allows to lock the photovoltaic module 3 on a support that has corresponding detent means, such as in particular plastic support 1, by placing the module thereon and then moving it laterally, wherein due to the mirror-symmetrical arrangement of hooks 37, locking may be effected selectively by lateral displacement along two opposing latching directions 38. For this reason, the latching direction 38 in FIG. 3 is represented as a double arrow. Latching in lateral direction is effected by engaging locking surfaces 370 at corresponding opposed locking surfaces of the respective support, so that each one of the locking surfaces 370 of the pair of hooks 37 blocks a movement in one lateral direction. Accordingly, latching in a direction parallel to the surface of the glass sheet or parallel to the front or back side of the photovoltaic module 3 may be accomplished by engaging locking surfaces 370 at fixed elements, such as corresponding locking surfaces of a support.

The resilient mounting of hooks 37 and guiding surfaces 371 thereof enable that during latching the trailing hook 37 with respect to the displacement direction 38 is raised as the inclined guiding surface 371 slides over a portion of the support and may resiliently spring hack after having passed the locking surface of the support so that the locking surfaces of the hook and of the support face each other.

In the embodiment shown in FIG. 3, the resilient mounting of hook 37 is provided by a leaf spring arm 372. If, as preferred, the module holders 33 are made of plastics, detent members 35, 37 including leaf spring arm 372 may be produced integrally in a simple manner. Differently than shown in FIG. 3, it is also conceivable to configure hooks 37 to be deflectable in a direction along front or back sides 30, 31.

This mounting and latching operation to plastic support 1 will be described in more detail below with reference to the other figures. In any case, the features of a photovoltaic module 3 according to the invention as described above may be summarized as follows, without being limited to the illustrated embodiments:

Photovoltaic module 3 is frameless and comprises at least one sheet covering the photovoltaicactive layer, preferably a glass sheet, which forms the front side of photovoltaic module 3, wherein module holders 33 are glued to the opposite, back side of photovoltaic module 3, and wherein each of the module holders 33 has a pair of resiliently deflectable detent members (hooks 37 in the embodiment shown in FIG. 3) at opposite ends of module holder 33, and wherein these detent members have locking surfaces 370 facing in opposite directions, and wherein the module holders 33, as described above, have further detent members (in FIG. 3 in particular detent lugs 35) with detent surfaces 350, wherein detent surfaces 350 have a component of the surface normal in parallel to the direction of the surface normal of the class sheet or the front or back side, to block a movement in the direction of this surface normal when being in contact with a detent member of a support.

Preferably, as mentioned above, a handle 39 is formed on the module holders, or expressed vice versa, module holders 33 are formed as handles 39.

Starting from the elements shown in FIGS. 1 and 3, FIG. 4 shows, in an enlarged view, a first method step for fixing a photovoltaic module 3 on plastic support 1.

In one embodiment of the invention, plastic support 1 has specifically configured module positioning means, which serves to safely position the photovoltaic module 3 before the actual securing step. Once photovoltaic module 3 is positioned, the hands may be displaced without risk.

These means are advantageous compared to conventional mounting systems since for mounting such systems often two installers are required, on the one hand to hold a module, and on the other to fix it.

For the assembly according to the invention, by contrast, photovoltaic module 3 may be placed with its edge 300 on support surface 105 so that edge 300 engages support edge 103 adjacent support surface 105, before the actual mounting operation.

Support edge 103 is arranged such that the photovoltaic module 3 when engaging this edge and being placed on support surface 105 is in a defined starting position for lateral displacement of the module along plastic support 1 for mutual locking of detent members 20, 22, 35, 37 of plastic support 1 and photovoltaic module 3. For the sake of clarity, support edge 103 and support surface 105 are also illustrated in FIG. 1.

As can be seen in FIG. 4, in the defined starting position detent lugs 35 of module holder 33 are arranged in front of the corresponding detent members 20 of plastic support 1, when regarded in the displacement direction.

For a more detailed illustration of the step of latching and securing photovoltaic module 3 on the plastic support, FIG. 5 shows a section of the photovoltaic installation system with the photovoltaic module 3 in locked state.

Detent members 20, as can also be seen from FIG. 4, are in form of projections or recesses at a molded shape 122, under which or into which detent lugs 35 are then slid when being displaced into the locked position. Mounting points 18 are also positioned on molded shape 122. Additionally, fixing screw 180 can be seen in FIG. 5, which is screwed through mounting points 18 and into the roof substructure.

In a refinement of the invention, photovoltaic modules 3 in the final mounted position are biased by a spring which prevents later rattling under windy conditions. To this end, a spring 181 is arranged under fixing screw 180, which spring biases the photovoltaic module 3 in the vertical direction and thus prevents a later rattling on the roof under wind stress.

As mentioned before, locking in the latching direction 38 or horizontal direction is effected by an engagement of locking surface 370 of hook 37, which is aligned transversely to the latching direction 38, with a corresponding locking surface of plastic support 1. This corresponding locking surface forms a detent member 22 for locking photovoltaic module 3 in horizontal direction. As can be seen from FIG. 5, this locking surface may simply be provided by a side wall 1001 of a bead 100. For locking, the trailing hook 37 with respect to the latching direction is moved over bead 100, the guiding surface 371 being raised by bead 100 during the displacement under resilient deflection of leaf spring arm 372, so that the hook 37 slides over bead 100. In the locked position, hook 37 has passes over bead 100 so that the spring force of leaf spring arm 372 then returns hook 37 into its vertical starting position as shown in FIG. 5 which brings locking surface 370 into opposed engaging position to side wall 1001 of bead 100. Thereby, locking surface 370 of hook 37 prevents a movement of the module in a horizontal direction, and the other, opposite hook 37 not shown in FIG. 5 prevents a movement in the opposite direction, so that by cooperation of the pair of hooks 37 of one module holder 33 with the side walls 1001 of plastic support 1, horizontal locking is effected in the direction parallel to the surface of the glass sheet.

An photovoltaic installation system according to the invention comprising a plastic support 1 and a photovoltaic module 3 is therefore generally characterized by detent members 20, 22, 35, 37 provided at the plastic support 1 and the photovoltaic module 3, which allow to lock photovoltaic module 3 on plastic support 1, wherein by placing photovoltaic module 3 in a starting position and laterally displacing photovoltaic module 3 on plastic support 1 into a locked position shown in FIG. 5, locking of the photovoltaic module 3 in both the horizontal direction along the surface of the glass sheet or along the front or back side and perpendicular thereto is effected, so that complete locking of the photovoltaic module 3 in all, directions is achieved.

The horizontal displacement of photovoltaic module 3 for locking purposes may be used in a in particularly advantageous manner as an anti-theft measure. The assembly of the modules by horizontally telescoping the modules to the substructure permits a simplified anti-theft measure for the entire module array. Since with side by side mounted plastic supports, the narrow gap between the photovoltaic modules 3 prevents a displacement of a single module of the module array if the required space to unlock the photovoltaic module 3 is larger than the width of the gap between the photovoltaic modules, it suffice to provide any type of anti-theft device at the respective outer modules.

In currently common on-roof or in-roof systems, by contrast, each individual module has to be equipped with an anti-theft device.

Therefore, according to one embodiment of the invention it is suggested that the width of the photovoltaic module as measured in latching direction 38 is greater than the width of the plastic support 1 in this direction minus the displacement path between the starting position and the locked position. A result thereof is that when assembling a plurality of modules on the plastic supports, the gap between photovoltaic modules 3 is smaller than the displacement path.

It will be understood by a person skilled in the art that the invention is not limited to the specific embodiments as illustrated in the figures. In particular, the individual features of the exemplary embodiments may be combined and modified within the scope of the appending claims. For example, the individual latching means that are provided on module holders 33 and plastic support 1 may be exchanged. To cite another example, it is also possible to reverse the orientation of hooks 37 so that the locking surfaces 370 face towards the center of module holder 33.

### LIST OF REFERENCE NUMERALS

1 Plastic support

3 Photovoltaic Module

10 Rainwater discharging element

11 Border of plastic support

12 Raised portion

14 Upper side of 1

16 Opening

18 Mounting point of 1

20, 22 Detent members of 1

30 Front side of 3

31 Back side of 3

32 Glass sheet

33 Module holder

35 Detent member

37 Detent member, hook of 3

38 Latching direction

39 Handle

100 Bead

101 Cable duct

103 Support edge

105 Support surface

107 Base plane of 1

110 Edge of plastic support 1

111 Transverse edge of plastic support 1

120 Edge of 12

121 Raised bead

122 Shape

180 Fixing screw

181 Spring

300 Edge of 3

310 Connection cable

312 Junction box

330 Gluing surface

350 Detent surface of 35

370 Locking surface of 37

371 Guiding surface of 37

372 Leaf spring arm

1. A plastic support (1) for a photovoltaic module (3) in form of a one-piece molded plastic element with a rectangular or square outline, which has elongated rainwater discharging elements (10) extending along one edge (110) of the plastic support (1), which in a tilted position of the plastic support (1) with a gradient direct rain water along the direction of elongation in a direction of the gradient, wherein the plastic support (1) further comprises a shape in form of a raised portion (12) at its upper side (14), with an edge (120) thereof spaced from the border (11) of the plastic support (1), and wherein mounting points (18) are provided on said raised portion (12) for passing fastening means through the plastic support (1) for fastening them to a substructure, and wherein the plastic support (1) further comprises detent members (20, 22) for snap fixing a photovoltaic module (3).

2. The plastic support (1) as claimed in claim 1, wherein the raised portion (12) is provided in form of a raised bead (121) which frames an opening (16).

3. The plastic support (1) as claimed in claim 1, comprising beads (100) as rainwater discharging elements (10) which are arranged at both sides of the raised portion (12) along the edge, wherein the upper and lower sides of the beads (100) are shaped complementary to one another so that two plastic supports (1) can be placed in laterally offset relationship one upon the other with interengaging beads (100).

4. The plastic support (1) as claimed in claim 1, wherein said plastic support (1) is made of a thermoplastic molding compound.

5. The plastic support (1) as claimed in claim 4, wherein the thermoplastic molding compound is based on polyamide having a viscosity number from 50 to 250 ml/g, preferably from 70 to 200 ml/g, and more preferably from 80 to 150 ml/g, as determined according to ISO 307 EN on a 0.5 wt % solution of the polyamide in 96 wt % sulfuric acid at 25° C.

6. The plastic support (1) as claimed in claim 1, wherein the thermoplastic molding compound comprises from 0 to 70 percent by weight, preferably from 10 to 60 percent by weight, more preferably from 20 to 50 percent by weight of fibrous or particulate fillers.

7. The plastic support (1) as claimed in claim 1, wherein the thermoplastic molding compound comprises pigments and/or stabilizers to improve the weather resistance and/or fire properties.

8. The plastic support (1) as claimed in claim 1, wherein the plastic support (1) is configured to be stackable by having an upper side and a lower side with an at least partially complementary shape, so that when placing one plastic support (1) with its lower side on top of another plastic support (1) with the edges aligned, the total height of the thus stacked two plastic supports (1) is less than twice the height of a single plastic support (1).

9. The plastic support (1) as claimed in claim 1, wherein the plastic support (1) comprises detent members (20) for locking in a direction perpendicular to the upper side of the plastic support (1), which are spaced from the closest mounting point (18) by not more than one sixth, preferably not more than one tenth of the longest lateral dimension of the plastic support (1).

10. The plastic support (1) as claimed in claim 1, comprising at least one cable guide element, preferably in form of a half-open cable channel (101) which extends above a base plane (107) of the plastic support (1).

11. A method for producing a plastic support (1) as claimed in claim 1, wherein the plastic support (1) is produced in an injection molding or injection compression molding process, and wherein a hot runner system with a plurality of hot runner nozzles is used for distributing the melt.

12. A photovoltaic module (3), in particular adapted for being fixed on a plastic support (1) as claimed in claim 1, wherein the photovoltaic module (3) is preferably frameless and comprises at least one glass sheet covering the photovoltaically active layer, said glass sheet forming the front side (30) of the photovoltaic module (3), wherein module holders (33) are glued to the back side (31) of the photovoltaic module (3) opposite the front side (30), and wherein each of said module holders (33) has a pair of resiliently deflectable detent members at opposite ends of the module holder (33), and wherein each of these detent members has locking surfaces (370) with a component of the surface normal in parallel to the surface of the glass sheet, so that by engaging these locking surfaces (370) at fixed elements locking is effectable in a direction in parallel to the surface of the glass sheet (32), and wherein the module holders (33) have further detent members (35) with detent surfaces (350) which have a component of the surface normal in parallel to the direction of the surface normal of the front side (30) or back side (31) to block a displacement in the direction of this surface normal when being in contact with a detent member of a support.

13. The photovoltaic module (3) as claimed in claim 12, wherein said module holders (33) are formed as handles (39).

14. A photovoltaic installation system with a plastic support (1) and a photovoltaic module (3), in particular as claimed in claim 1, comprising detent members (20, 22, 35, 37) at said plastic support (1) and at said photovoltaic module (3), by means of which locking of the photovoltaic module (3) on the plastic support (1) is effectable both in the horizontal direction along the front side or back side of the photovoltaic module (3) and perpendicular thereto, by placing the photovoltaic module (3) in a starting position and laterally displacing the photovoltaic module (3) on the plastic support (1) into a latched position, so that complete locking of the photovoltaic module in all directions (3) is effectable.

15. The photovoltaic installation system as claimed in claim 14, wherein the plastic support (1) has a support surface (105) and a support edge (103) adjacent the support surface, which are positioned such that when the photovoltaic module (3) is engaged at the support edge (103) and placed on the support surface (105) it comes to rest in a defined starting position for the lateral displacement of the photovoltaic module (3) along the plastic support (1) for interengaging the detent members (20, 22, 35, 37) of the plastic support (1) and of the photovoltaic module (3).

16. The photovoltaic installation system as claimed in claim 14, wherein the width of the photovoltaic module (3) measured in the latching direction (38) is greater than the width of the plastic support (1) in this direction minus the displacement path between the starting position and the latched position.
